(19) United States
(12) Patent Application Publication
(10) Pub. No.: US 2025/0133672 A1
(43) Pub. Date: Apr. 24, 2025

(54) DATA TRANSFER CARTRIDGE

(71) Applicant: ITI Engineering, LLC, Winter Springs, FL (US)

(72) Inventors: Eugenio Diaz, Winter Springs, FL (US); Mariela Barragan, Winter Springs, FL (US)

(73) Assignee: ITI Engineering, LLC, Winter Springs, FL (US)

(21) Appl. No.: 18/923,804

(22) Filed: Oct. 23, 2024

Related U.S. Application Data
(60) Provisional application No. 63/592,217, filed on Oct. 23, 2023.

(51) Int. Cl. H05K 5/02

(52) U.S. Cl. CPC H05K 5/026

(57) ABSTRACT

A system for transferring data including (1) a plurality of signal traces; (2) a first connector in electrical connection with the plurality of signal traces; (3) a second connector in electrical connection with a first portion of the plurality of signal traces; (4) a third connector in electrical connection with a second portion of the plurality of signals traces; (5) a switch adapted to receive at least one control signal from the first connector, to receive an input data channel from the first connector, and to provide a plurality of output data channels; and (6) a reset control module adapted to receive a first one of the plurality of output data channels from the switch and provide a first reset signal to the second connector and a second reset signal to the third connector.

### RELATED APPLICATIONS

This application claims priority under 35 U.S.C. § 119 (e) of U.S. Provisional Patent Application Ser. No. 63/592,217 (Attorney Docket No. 7687.00003) filed on Oct. 23, 2023 and titled DATA TRANSFER CARTRIDGE. The content of this application is incorporated herein by reference.

### FIELD OF THE INVENTION

The present invention relates to systems and methods for transferring data from one device to two similar devices.

### BACKGROUND OF THE INVENTION

There is often a need to transfer large volumes of data on systems using VPX standards. Therefore a need exists for a device to facilitate transfer of 8 lanes of PCIe signals to two identical SSD cards with four lanes of the PCIe data going to each of the SSDs.

This background information is provided to reveal information believed by the applicant to be of possible relevance to the present invention. No admission is necessarily intended, nor should be construed, that any of the preceding information constitutes prior art against the present invention.

### SUMMARY OF THE INVENTION

With the above in mind, embodiments of the present invention are related to a system for transferring data including a plurality of signal traces; a first connector; a second connector; a third connector; a switch, and a reset control module. The first connector may be in electrical connection with the plurality of signal traces. The second connector may be in electrical connection with a first portion of the plurality of signal traces. The third connector may be in electrical connection with a second portion of the plurality of signals traces. The switch may be adapted to receive at least one control signal from the first connector, to receive an input data channel from the first connector, and to provide a plurality of output data channels. The reset control module may be adapted to receive a first one of the plurality of output data channels from the switch and provide a first reset signal to the second connector and a second reset signal to the third connector.

The first portion of the plurality of signal traces may implement at least a first lane of a PCIe interface. The second portion of the plurality of signal traces may implement at least a second lane of the PCIe interface.

The first portion of the plurality of signal traces may include a first four lanes of a PCIe interface and the second portion of the plurality of signal traces may include a second four lanes of the PCIe interface.

The system may further include a buffer adapted to receive a reference clock signal from the first connector, to provide a first clock signal to the second connector, and to provide a second clock signal to the third connector.

The value of the at least one control signal provided to the switch may select which of the plurality of output data channels is in electrical communication with the input data channel.

The switch may be adapted to provide a second output data channel to the second connector and to provide a third output data channel to the third connector.

The system may further include an EEPROM. The switch may be adapted to provide a fourth output data channel to the EEPROM.

The reset control module may be further adapted to provide a first power disable signal to the second connector and a second power disable signal to the third connector.

The reset control module may be adapted to perform a first reset sequence including the steps of (1) transitioning the first power disable signal from high to low prior to (2) transitioning the first reset signal from low to high.

The reset control module may be adapted to perform a second reset sequence comprising the steps of (1) transitioning the second power disable signal from high to low prior to (2) transitioning the second reset signal from low to high.

The reset control module may be adapted to not transition the first power disable signal from high to low simultaneously with transitioning the second power disable signal from high to low.

The system may comply with VPX standards.

### BRIEF DESCRIPTION OF THE DRAWINGS

Some embodiments of the present invention are illustrated as an example and are not limited by the figures of the accompanying drawings, in which like references may indicate similar elements.

FIG. 1 is a block diagram of a system for transferring data according to an embodiment of the present invention.

FIG. 2 is a timing diagram of select signals of the system for transferring data of FIG. 1.

FIG. 3 is an exploded view of the system of FIG. 1.

FIG. 4 is a top plan view of the system of FIG. 1.

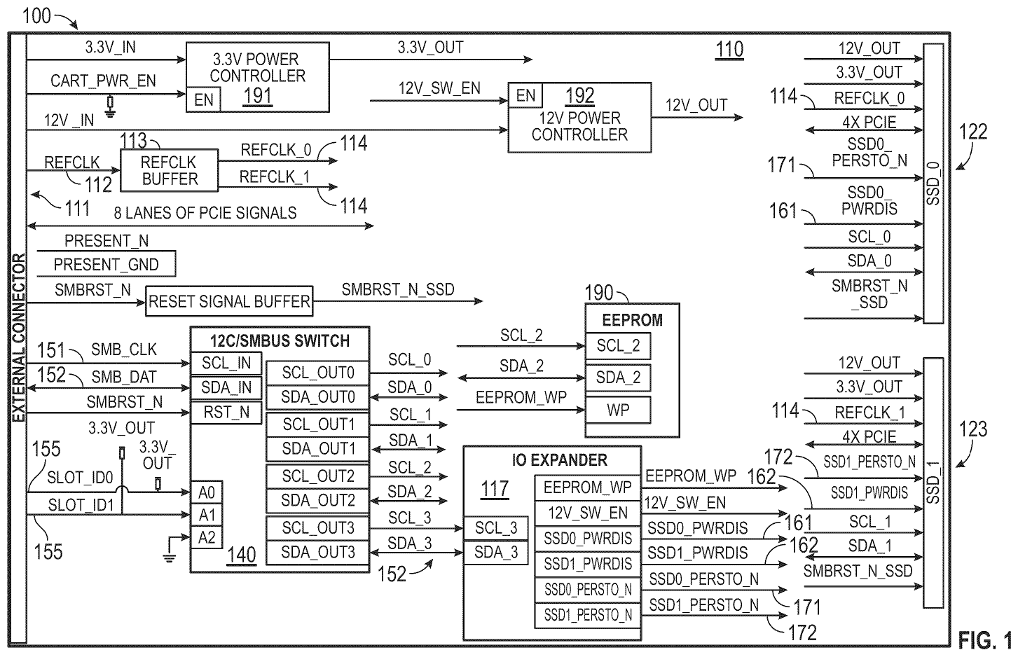

### DETAILED DESCRIPTION OF THE INVENTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Those of ordinary skill in the art realize that the following descriptions of the embodiments of the present invention are illustrative and are not intended to be limiting in any way. Other embodiments of the present invention will readily suggest themselves to such skilled persons having the benefit of this disclosure. Like numbers refer to like elements throughout.

Although the following detailed description contains many specifics for the purposes of illustration, anyone of ordinary skill in the art will appreciate that many variations and alterations to the following details are within the scope of the invention. Accordingly, the following embodiments of the invention are set forth without any loss of generality to, and without imposing limitations upon, the claimed invention.

In this detailed description of the present invention, a person skilled in the art should note that directional terms, such as “above,” “below,” “upper,” “lower,” and other like terms are used for the convenience of the reader in reference to the drawings. Also, a person skilled in the art should notice this description may contain other terminology to convey position, orientation, and direction without departing from the principles of the present invention.

Furthermore, in this detailed description, a person skilled in the art should note that quantitative qualifying terms such as “generally,” “substantially,” “mostly,” and other terms are used, in general, to mean that the referred to object, characteristic, or quality constitutes a majority of the subject of the reference. The meaning of any of these terms is dependent upon the context within which it is used, and the meaning may be expressly modified.

An embodiment of the invention, as shown and described by the various figures and accompanying text, provides a system for transferring data 100. The system for transferring data 100 may include a plurality of traces 180, a first connector 111, a second connector 122, a third connector 123, a switch 140, and a reset control module 117. The second connector 122 may be adapted to form a physical and electrical connection with a first endpoint 120 and the third connector 123 may be adapted to form a physical and electrical connection with a second endpoint 120. Each endpoint 120 may implement a data transfer protocol. By way of example, and not as a limitation, the data transfer protocol may be PCI Express (PCIe).

A plurality of trace 180 may be in electrical connection with the first connector 111. In one embodiment, the plurality of traces 180 may implement the data transfer protocol, which may be PCIe. A first portion of the plurality of traces 180 may be in electrical connection with the second connector 122 and a second portion of the plurality of traces 180 may be in electrical connection with the third connector 123. The first portion of the plurality of traces may implement a lane of the PCIe interface and the second portion of the plurality of traces 180 may implement a different lane of the PCIe interface. In one embodiment, the plurality of traces 180 may implement 8 lanes of a PCIe interface, first portion of the plurality of traces may implement lanes 1-4 of the PCIe interface and the second portion of the plurality of traces may implement lanes 5-8 of the PCIe interface.

The system 100 may also include a storage interface board 110. The storage interface board 110 may provide a substrate for mounting the first connector 111, second connector 122, third connector 123, switch 140, or reset control module 117. The first connector 111 may be any connector adapted to form physical and electrical connections with a device external to the system 100. In one embodiment, the first connector 111 may be an industrial standard connector, which may be ruggedized. By way of example, and not as a limitation, the external connector 111 may meet the standards required by VPX for connectors, which VPX standards are hereby incorporated by reference. In one embodiment, the system 100 may comply with all VPX standards.

The first connector 111 may receive a reference clock input 112 from a device external to the system 100 and this reference clock signal 112 may be provided to a reference clock buffer 113 carried by the storage interface board 110. The reference clock buffer 113 may output a separate reference clock signal 114 to each of the second connector 122 and third connector 123.

The first connector 111 may also receive a clock 151 and data 152 signals to enable the operation of the data transfer protocol on multiple endpoints 120. In one embodiment, the clock 151 and data 152 signals may implement an 12C interface. The data signals 152 may include selection data information to select which endpoint 120 is transmitting or receiving data. The selection data information may be written to a register in the reset control module 117, which may be utilized to control one or more output of the reset control module 117 to enable either one of the endpoints 120, neither of the endpoints 120, or both endpoints 120 to transmit or receive data.

The switch 140 may receive at least one switch control signal 155 from the first connector 111. The switch 140 may also receive an input data channel and provide a plurality of output data channels. The value of the switch control signal 155 may determine which of the plurality of output data channels is in electrical communication with the input data channel. In one embodiment, the switch 140 may have at least four output data channels. A first output data channel may be in electrical communication with the reset control module 117. A second output data channel may be in electrical communication with the second connector 122. A third output data channel may be in electrical communication with the third connector 123. A fourth output data channel may be in electrical communication with an EEPROM 190 included in the system 100 and located on the storage interface board 110. The switch control signal 155 may be configured to select any combination of the channels.

When switch control signals 155 provided from the first connector 111 to the switch 140 select the output data channel in electrical communication with the reset control module 117 to receive the input data signal 152 provided from the first connector 111 to the switch 111, the switch 111 may output the data signal 152 to the reset control module 117. The value of the output data signal received by the reset control module 117 may determine the value of the control signals provided to the second connector 122 and third connector 123 to enable or reset different endpoints 120 secured to the second connector 122 and third connector 123. The reset control module 117 may output a first power disable signal 161 to the second connector 122, a first reset signal 171 to the second connector 122, a second power disable signal 162 to the third connector 123, and a second reset signal 172 to the third connector 123.

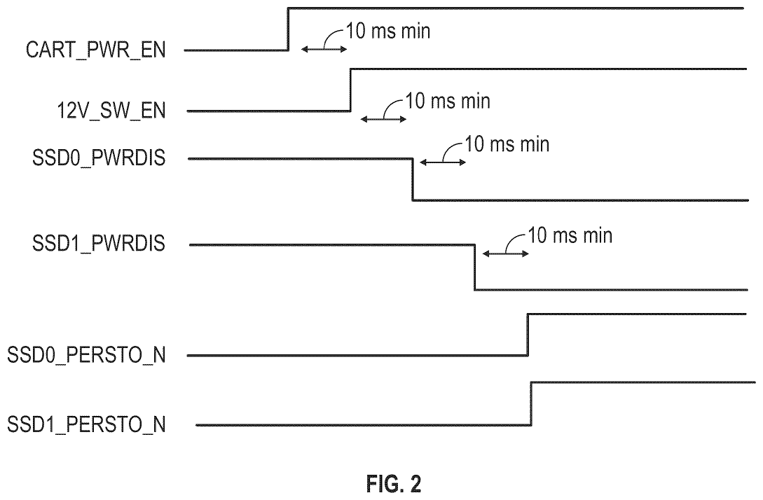

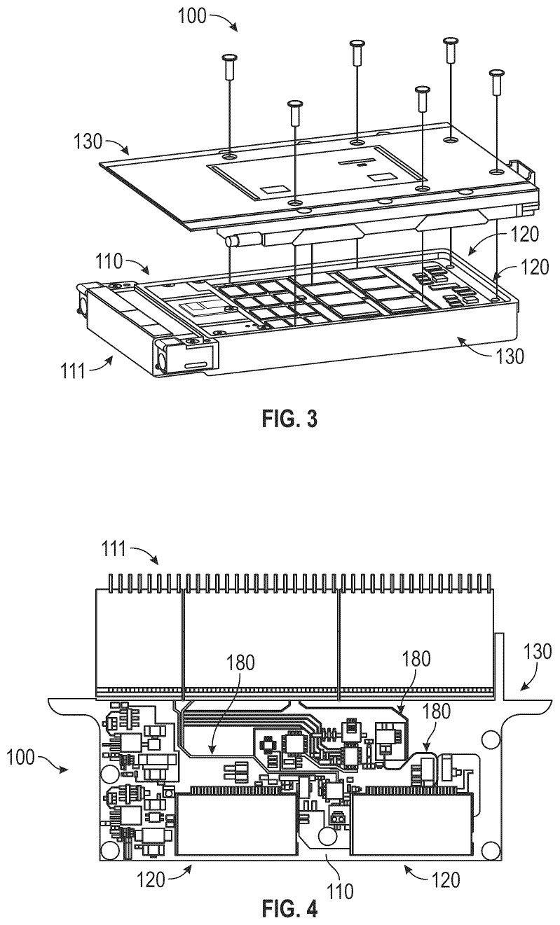

Turning to FIG. 2, a timing sequence for both a first and second reset sequence is shown. The signals labeled SSD0 are provided from the reset control module 117 to the second connector 122 and the signals labeled SSD1 are provided from the reset control module 117 to the third connector 123. The cart_pwr_en signal is provided to a first power controller 191 to enable power of a first voltage level to be provided to both the second controller 122 and the third controller 123. The 12v_sw_en signal is provided to a second power controller 192 to enable power of a second voltage level to be provided to both the second controller 122 and the third controller 123. The signal labeled SSDX_PWRDIS may be referred to as a power disable signal is brought low to enable power to the associated endpoint. The signal labeled SSDX_PERSTO_N may be referred to as a reset signal and may be brought from low to high to bring the associated endpoint out of reset. A reset sequence for an associated endpoint requires transitioning the power disable signal from high to low prior to transitioning the reset signal for the same endpoint from low to high. In one embodiment, each step of the reset sequence must be performed at least 10 milliseconds prior to the next step. Similarly, each power level must be enabled at least 10 milliseconds prior to enabling the other power level or initiating the reset signal. In one embodiment, the system 100 may be prevented from transitioning both power disable signals from high to low simultaneously. However, both endpoints may be brought out of reset simultaneously.

The reset control module 117 may be configured to implement a management bus to allow for the monitoring of health and other parameters of each endpoint 120. In one embodiment, by way of example, and not as a limitation, the data transfer control and data signals may be implemented with a system management bus (SMBus). The switch 140 may have a plurality of other channels, each of which is in electrical communication with SMBus signals from one of the endpoints 120.

The data transfer cartridge 100 may include a housing 130 to carry the storage interface board 110 and each of the second connector 122 and third connector 123. The first connector 111 may be secured to the housing 130 and accessible external to the housing 130.

Some of the illustrative aspects of the present invention may be advantageous in solving the problems herein described and other problems not discussed which are discoverable by a skilled artisan.

While the above description contains much specificity, these should not be construed as limitations on the scope of any embodiment, but as exemplifications of the presented embodiments thereof. Many other ramifications and variations are possible within the teachings of the various embodiments. While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best or only mode contemplated for carrying out this invention, but that the invention will include all embodiments falling within the scope of the appended claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item.

Thus the scope of the invention should be determined by the appended claims and their legal equivalents, and not by the examples given.

What is claimed is:

1. A system for transferring data comprising:
a plurality of signal traces;
a first connector in electrical connection with the plurality of signal traces;
a second connector in electrical connection with a first portion of the plurality of signal traces;
a third connector in electrical connection with a second portion of the plurality of signals traces;
a switch adapted to receive at least one control signal from the first connector, to receive an input data channel from the first connector, and to provide a plurality of output data channels; and
a reset control module adapted to receive a first one of the plurality of output data channels from the switch and provide a first reset signal to the second connector and a second reset signal to the third connector.

2. The system of claim 1 wherein the first portion of the plurality of signal traces implements at least a first lane of a PCIe interface and wherein the second portion of the plurality of signal traces implements at least a second lane of the PCIe interface.

3. The system of claim 1 wherein the first portion of the plurality of signal traces comprises a first four lanes of a PCIe interface and the second portion of the plurality of signal traces comprises a second four lanes of the PCIe interface.

4. The system of claim 1 further comprising a buffer adapted to receive a reference clock signal from the first connector, to provide a first clock signal to the second connector, and to provide a second clock signal to the third connector.

5. The system of claim 1 wherein the value of the at least one control signal selects which of the plurality of output data channels is in electrical communication with the input data channel.

6. The system of claim 1 wherein the switch is adapted to provide a second output data channel to the second connector and to provide a third output data channel to the third connector.

7. The system of claim 6 further comprising an EEPROM and wherein the switch is adapted to provide a fourth output data channel to the EEPROM.

8. The system of claim 1 wherein the reset control module is further adapted to provide a first power disable signal to the second connector and a second power disable signal to the third connector.

9. The system of claim 8 wherein the reset control module is adapted to perform a first reset sequence comprising the steps of transitioning the first power disable signal from high to low prior to transitioning the first reset signal from low to high.

10. The system of claim 9 wherein the reset control module is adapted to perform a second reset sequence comprising the steps of transitioning the second power disable signal from high to low prior to transitioning the second reset signal from low to high.

11. The system of claim 10 wherein the reset control module is adapted to not transition the first power disable signal from high to low simultaneously with transitioning the second power disable signal from high to low.

12. The system of claim 1 wherein the system complies with VPX standards.

13. A system for transferring data comprising:
a plurality of signal traces;
a first connector in electrical connection with a first lane of a PCIe interface and a second lane of the PCIe interface;
a second connector in electrical connection with the first lane of the PCIe interface;
a third connector in electrical connection with the second lane of the PCIe interface;
a switch adapted to receive at least one control signal from the first connector, to receive an input data channel, and to provide a plurality of output data channels; and
a reset control module adapted to receive a first one of the plurality of output data channels from the switch and provide a first reset signal to the second connector and a second reset signal to the third connector.

14. The system of claim 13 further comprising a buffer adapted to receive a reference clock signal from the first connector, to provide a first clock signal to the second connector, and to provide a second clock signal to the third connector.

15. The system of claim 13 wherein switch is adapted to provide a second output data channel to the second connector and to provide a third output data channel to the third connector.

16. The system of claim 13 wherein the reset control module is further adapted to provide a first power disable signal to the second connector and a second power disable signal to the third connector.

17. The system of claim 16 wherein the reset control module is adapted to perform a first reset sequence comprising the steps of transitioning the first power disable signal from high to low prior to transitioning the first reset signal from low to high.

18. The system of claim 17 wherein the reset control module is adapted to perform a second reset sequence comprising the steps of transitioning the second power disable signal from high to low prior to transitioning the second reset signal from low to high.

19. The system of claim 18 wherein the reset control module is adapted to not transition the first power disable signal from high to low simultaneously with transitioning the second power disable signal from high to low.

20. A system for transferring data comprising:
a plurality of signal traces;
a first connector in electrical connection with a first lane of a PCIe interface and a second lane of the PCIe interface;
a second connector in electrical connection with the first lane of the PCIe interface;
a third connector in electrical connection with the second lane of the PCIe interface;
a switch adapted to receive at least one control signal from the first connector, to receive an input data channel, and to provide a first output data channel to the second connector and to provide a second output data channel to the third connector;
a reset control module adapted to receive a third output data channel from the switch, provide a first reset signal to the second connector, provide a second reset signal to the third connector, provide a first power disable signal to the second connector, provide a second power disable signal to the third connector, perform a first reset sequence comprising the steps of transitioning the first power disable signal from high to low prior to transitioning the first reset signal from low to high, perform a second reset sequence comprising the steps of transitioning the second power disable signal from high to low prior to transitioning the second reset signal from low to high, and to not transition the first power disable signal from high to low simultaneously with transitioning the second power disable signal from high to low; and
a buffer adapted to receive a reference clock signal from the first connector, to provide a first clock signal to the second connector, and to provide a second clock signal to the third connector.
